(19) United States
(12) Patent Application Publication
(10) Pub. No.: US 2025/0077759 A1
(43) Pub. Date: Mar. 6, 2025

(54) LAYOUT AND SCHEMATIC INCONSISTENCY CHECKING ACROSS HIERARCHICAL BOUNDARIES AND PREVENTATIVE DESIGN CONVENTIONS

(71) Applicant: International Business Machines Corporation, Armonk, NY (US)

(72) Inventors: Tobias Werner, Weil im Schoenbuch (DE); Miles C. Pedrone, Highland, NY (US); Ananth Nag Raja Darla, Bangalore (IN); AMIT BIPINBHAI PATEL, Bengaluru (IN); Muhammad Suleiman, Nazareth (IL)

(21) Appl. No.: 18/460,908

(22) Filed: Sep. 5, 2023

(51) Int. Cl. G06F 30/398; G06F 30/392

(52) U.S. Cl. CPC G06F 30/398; G06F 30/392

(57) ABSTRACT

A computer-implemented method for layout versus schematic (LVS) checking for a design process of an integrated circuit (IC) is provided. The computer-implemented method includes receiving a layout of the IC at multiple hierarchical levels, receiving a schematic of the IC at the multiple hierarchical levels, establishing a requirement for name matching, scanning the layout and the schematic at least at one of the multiple hierarchical levels and issuing an alert for one or more name inconsistencies identified during the scanning.

### BACKGROUND

The present invention generally relates to integrated circuits (ICs), and more specifically, to IC fabrication using layout and schematic inconsistency checking across hierarchical boundaries and preventative design conventions.

In the fabrication of an IC, physical verification of circuit layouts is an important process and is particularly vital during early stages of technology development in which circuits intended for technology ramp-up and device modeling are produced. Layout versus schematic (LVS) comparison is a well-known computerized verification method for determining whether a circuit layout corresponds to an input schematic diagram/design for the intended circuit. However, it has been found that LVS techniques are not always efficient, especially when dealing with circuit layouts with large arrays of devices. In those cases, manual processes can be performed to verify a circuit layout, but manual verification introduces its own disadvantages.

### SUMMARY

Embodiments of the present invention are directed to a computer-implemented method for layout versus schematic (LVS) checking for a design process of an integrated circuit (IC). The computer-implemented method includes receiving a layout of the IC at multiple hierarchical levels, receiving a schematic of the IC at the multiple hierarchical levels, establishing a requirement for name matching, scanning the layout and the schematic at least at one of the multiple hierarchical levels and issuing an alert for one or more name inconsistencies identified during the scanning.

Embodiments of the present invention are directed to a computer program product for layout versus schematic (LVS) checking for a design process of an integrated circuit (IC). The computer program product includes one or more computer readable storage media having computer readable program code collectively stored on the one or more computer readable storage media. The computer readable program code is executed by a processor of a computer system to cause the computer system to perform a method. The method includes receiving a layout of the IC at multiple hierarchical levels, receiving a schematic of the IC at the multiple hierarchical levels, establishing a requirement for name matching, scanning the layout and the schematic at least at one of the multiple hierarchical levels and issuing an alert for one or more name inconsistencies identified during the scanning.

Embodiments of the present invention are directed to a computing system including a processor, a memory coupled to the processor and one or more computer readable storage media coupled to the processor. The one or more computer readable storage media collectively contain instructions that are executed by the processor via the memory to cause the processor to perform steps for layout versus schematic (LVS) checking for a design process of an integrated circuit (IC). The steps for the LVS checking for the design process of the IC include receiving a layout of the IC at multiple hierarchical levels, receiving a schematic of the IC at the multiple hierarchical levels, establishing a requirement for name matching, scanning the layout and the schematic at least at one of the multiple hierarchical levels and issuing an alert for one or more name inconsistencies identified during the scanning.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 is a schematic diagram of a computing environment for executing a computer-implemented method for selectively capturing traffic in a service mesh to simulate and address an issue with a service invoke chain in accordance with one or more embodiments of the present invention;

FIG. 2 is a flow diagram illustrating a computer-implemented method for layout versus schematic (LVS) checking for a design process of an integrated circuit (IC) in accordance with one or more embodiments of the present invention;

FIG. 3 is a schematic graphical diagram illustrating an instance of cell name mismatch that is correctable by the computer-implemented method of FIG. 2 in accordance with one or more embodiments of the present invention;

FIG. 4 is a schematic graphical diagram illustrating an instance of instance name mismatch that is correctable by the computer-implemented method of FIG. 2 in accordance with one or more embodiments of the present invention;

FIG. 5 is a schematic graphical diagram illustrating an instance of pin name mismatch that is correctable by the computer-implemented method of FIG. 2 in accordance with one or more embodiments of the present invention; and

FIG. 6 is a schematic graphical diagram illustrating an instance of missing layout identification that is executable by the computer-implemented method of FIG. 2 in accordance with one or more embodiments of the present invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the disclosed embodiments, the various elements illustrated in the figures are provided with two or three digit reference numbers. With minor exceptions, the leftmost digit(s) of each reference number correspond to the figure in which its element is first illustrated.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

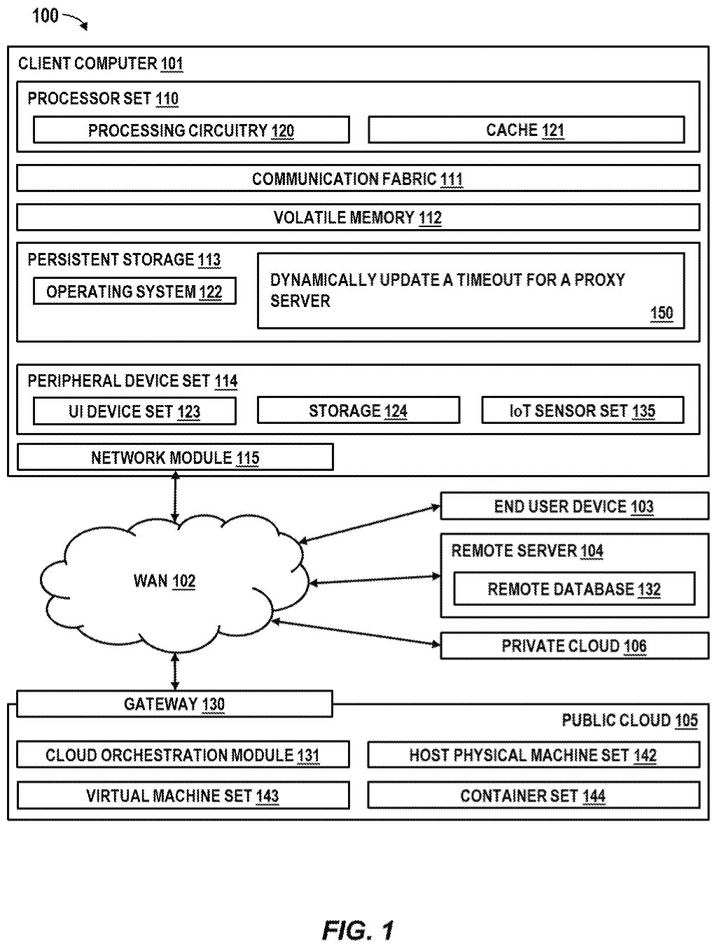

With reference to FIG. 1, a computer or computing device 100 that implements a computer-implemented method for

in accordance with one or more embodiments of the present invention is provided. The computer or computing device 100 of FIG. 1 contains an example of an environment for the execution of at least some of the computer code involved in performing the inventive methods, such as the block 1001 of the computer-implemented method for LVS checking for a design process of an IC. In addition to the computer-implemented method for the LVS checking for the design process of the IC of block 1001, the computer or computing device 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and the computer-implemented method of block 1001, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

The computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of the computer-implemented method, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

The processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In the computer-implemented method, at least some of the instructions for performing the inventive methods may be stored in the block 1001 of the computer-implemented method in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in the block 1001 of the computer-implemented method typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Turning now to an overview of technologies that are more specifically relevant to aspects of the invention, layout versus schematic (LVS) checking is used to compare physical and logical connectivity and to determine whether this physical and logical connectivity is correct and consistent across multiple hierarchical levels. It has been found, however, that final LVS results can be enormously complex especially when dealing with ICs having millions or billions of electrical devices. This can make the subsequent process of identifying problems and addressing those problems in the design tedious and time consuming.

While methods have been proposed to proactively identify potential problems in isolation, e.g. stand-alone IPs or macros, these methods tend to be limited. That is, the methods may not identify inconsistencies at one hierarchical level, but if those inconsistencies do exist, they can ultimately arise at higher hierarchical levels (i.e., unit-, continent- and chip-level LVS checking).

As an example, certain macros can be regarded as LVS clean in a standalone sense but still fail in a unit context. This can be due to various factors including, but not limited to, a same schematic pointing to different layouts in different macros and inconsistent sub-cell pin names between a layout and a schematic.

Turning now to an overview of the aspects of the invention, one or more embodiments of the invention address shortcomings of the above-described approaches by providing for a computer-implemented method that identifies inconsistencies in multi-level (cross-hierarchical) designs that are obfuscated with existing flows, processes and conventions resulting in failure to pass LVS checks. This is achieved through stringently stipulated design conventions of layouts and schematics and their integration to larger design flows. This is also achieved by automating known (identified) exceptions to integrate into higher hierarchical levels and to prevent propagations of inconsistencies. In sum, the computer-implemented method identifies, rectifies and automates LVS design inconsistencies throughout design processes.

The above-described aspects of the invention address the shortcomings of known approaches by providing for a computer-implemented method for LVS checking for a design process of an IC. The computer-implemented method includes receiving a layout of the IC at multiple hierarchical levels, receiving a schematic of the IC at the multiple hierarchical levels, establishing a requirement for name matching, scanning the layout and the schematic at least at one of the multiple hierarchical levels and issuing an alert for one or more name inconsistencies identified during the scanning.

As such, through automated identification and requiring stringent design conventions, it is possible to prevent inconsistencies before those inconsistencies are encountered at upper hierarchical levels by essentially enforcing same schematic and layout naming conventions and by requiring LVS equivalence between different cellNames for layouts and schematics in only certain expected cases.

Notably, the stringent, stipulated matching requirements described above are not always required to achieve “passing” or “allowed” designs in standard LVS checking in a single layer of hierarchy. In fact, in some instances, the inconsistencies will only be present in a higher level or levels of hierarchy where it is assumed the designs are “passing” or “allowed” by LVS checking. Thus, one or more embodiments of the present invention are directed to “scorched earth” policies for LVS checking. That is, the stipulated conventions for naming consistency exists whether there is a guarantee (known occurrence) of an inconsistency or not. The result is that the stipulated conventions for naming consistency effectively prevent eventualities of failures at a single hierarchical level and at higher hierarchical levels as well (i.e., any possible occurrence) from existing in the design. This in turn prevents systematic propagation of inconsistencies (“failing” or “disallowed” designs) throughout the design hierarchy.

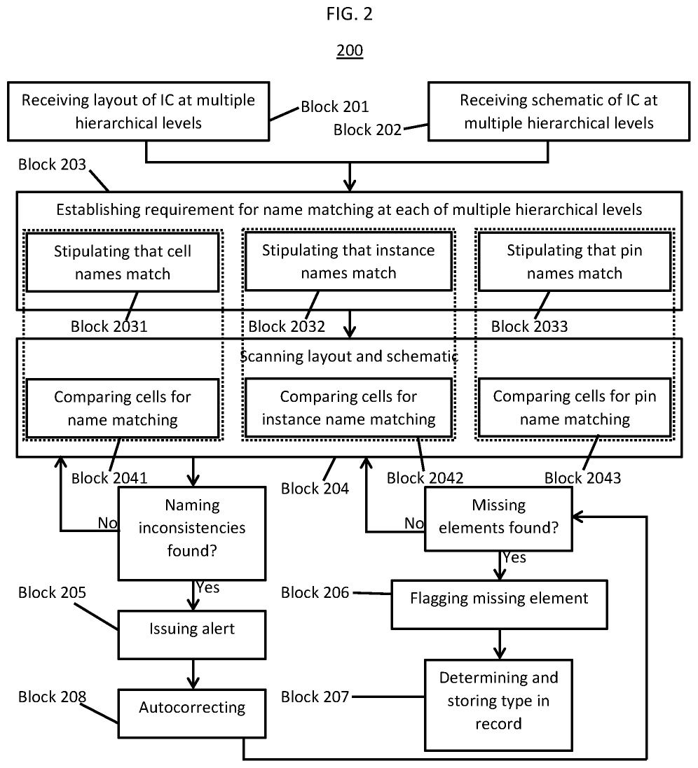

With reference to FIG. 2, a computer-implemented method 200 for LVS checking for a design process of an IC is provided. As shown in FIG. 2, the computer-implemented method 200 includes receiving a layout of the IC at multiple hierarchical levels (block 201) and receiving a schematic of the IC at the multiple hierarchical levels (block 202). In addition, as shown in FIG. 2, the computer-implemented method 200 includes establishing a requirement for name matching at each of the multiple hierarchical levels (block 203), scanning the layout and the schematic at least at one of the multiple hierarchical levels (block 204) and issuing an alert for one or more name inconsistencies identified during the scanning (block 205). Also, as shown in FIG. 2, the computer-implemented method 200 can include flagging a missing element in at least the layout that is discovered during the scanning of block 204 (block 206) and determining a type of the missing element and storing the type in a record (block 207) as well as automatically correcting the one or more name inconsistencies (block 208) in an event that any such name inconsistencies are found.

In accordance with one or more embodiments of the present invention, the scanning of block 204 can include comparing cells at one of the multiple hierarchical levels of the layout and the schematic for cell name matching (block 2041) with the establishing of the requirement for name matching of block 203 including stipulating that cell names match between the layout and the schematic for the one of the multiple hierarchical levels (block 2031).

In accordance with one or more embodiments of the present invention, the scanning of block 204 can include comparing cells at one of the multiple hierarchical levels of the layout and the schematic for instance name matching (block 2042) with the establishing of the requirement for name matching of block 203 including stipulating that instance names match between the layout and the schematic for the one of the multiple hierarchical levels (block 2032).

In accordance with one or more embodiments of the present invention, the scanning of block 204 can include comparing pins for every cell at one of the multiple hierarchical levels of the layout and the schematic for pin name matching (block 2043) with the establishing of the requirement for name matching of block 203 including stipulating that pin names match between the layout and the schematic for the one of the multiple hierarchical levels (block 2033).

It is to be understood that each of the above-described embodiments of the scanning of block 204 and the establishing of the requirement for name matching of block 203 can be executed jointly or separately.

Thus, the computer-implemented method 200 of FIG. 2 provides for cell mismatch detection, instance mismatch detection, pin mismatch detection, missing layout identification and an LVS automated fixing capability. Regarding, cell mismatch detection, cells are compared for same instances names, which may pass LVS checking in isolation but might fail during progression up a design hierarchy. In these or other cases, it is stipulated that cell names between cells and instances match. This solves for the problem of name inconsistency and prevents propagation of errors in a design hierarchy. Regarding instance mismatch detection, for every cell in a schematic hierarchy, schematic and layout instance names are compared with the understanding that they may pass LVS checking in isolation but fail during progression up a design hierarchy. In these or other cases, it is stipulated that instance names between cells and instances match. This solves for the problem of name inconsistency and prevents propagation of errors in a design hierarchy. Regarding pin mismatch detection, for every cell in a schematic hierarchy, schematic and layout pins are compared with the understanding that they may pass LVS checking in isolation but fail during progression up a design hierarchy. In these or other cases, it is stipulated that pin names between cells and instances match. This solves for the problem of name inconsistency and prevents propagation of errors in a design hierarchy. Regarding missing layout identification, for every schematic hierarchy, schematic and layout instances are flagged if any are found to be missing. In these or other cases, it is to be understood that, while not all cases of missing instances cause failures, such as the cases of parameterized cells being allowed to be missing, some instances of missing layouts to cause failures. In such cases, knowledge of which types of cells are missing can prevent inconsistencies. Regarding LVS automated fixing capability, it is possible to generate and provide a script to cleanup inconsistencies in a layout based on a corresponding LVS run, especially where knowledge of inconsistency types can be propagated to higher hierarchical levels for automatic rectification (unless an exception waiver granted).

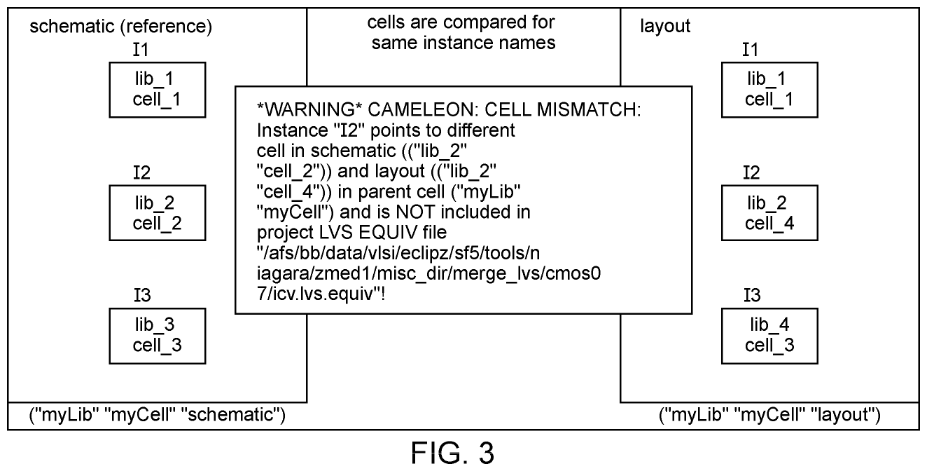

With reference to FIG. 3, a schematic graphical diagram is provided to illustrate an instance of cell name mismatch that is correctable by the computer-implemented method 200 of FIG. 2. As shown in FIG. 3, a layout of an IC differs from a schematic of the IC in that instances 12 and 13 have different library or cell names in the layout than they do in the schematic. Instance 12 in the layout is named lib-2;cell-4 whereas instance 12 in the schematic is named lib-2;cell-2 and instance 13 in the layout is named lib-4;cell 3 whereas instance 13 in the schematic is named lib-3;cell-3. In this case, even if the actual physical components of the differently named instances are the same, the mere fact of the different library or cell names would be enough to fail LVS checking. This prevents any potential problems from existing and propagating throughout higher hierarchical levels.

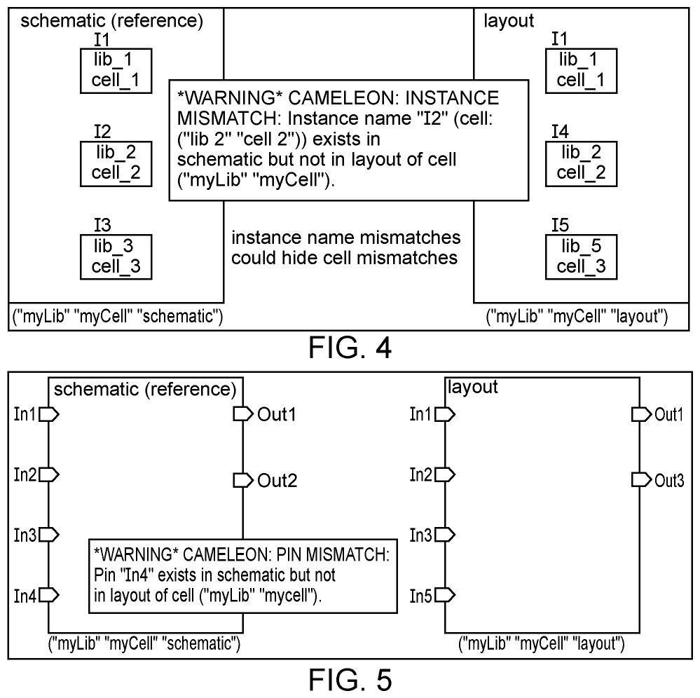

With reference to FIG. 4, a schematic graphical diagram is provided to illustrate an instance of an instance mismatch that is correctable by the computer-implemented method 200 of FIG. 2. As shown in FIG. 4, a layout of an IC differs from a schematic of the IC in that instances 14 and 15 in the layout have instance names 14 and 15 that differ from that of the schematic, which has instance names 12 and 13, and thus can hide a cell mismatch. In this case, as above, even if the actual physical components of the instances are the same (see, e.g., instance 14 in the layout has lib-2;cell-2 which is the same internally as instance 12 in the schematic), the mere fact of the different instance names would be enough to fail LVS checking. This prevents any potential problems from existing and propagating throughout higher hierarchical levels.

With reference to FIG. 5, a schematic graphical diagram is provided to illustrate an instance of pin name mismatch that is correctable by the computer-implemented method 200 of FIG. 2. As shown in FIG. 5, pins In4 and Out2 exist in the schematic but are missing from the layout. In this case, as above, even if the actual physical components and locations of the pins are the same, the mere fact of the different pin names would be enough to fail LVS checking. This prevents any potential problems from existing and propagating throughout higher hierarchical levels.

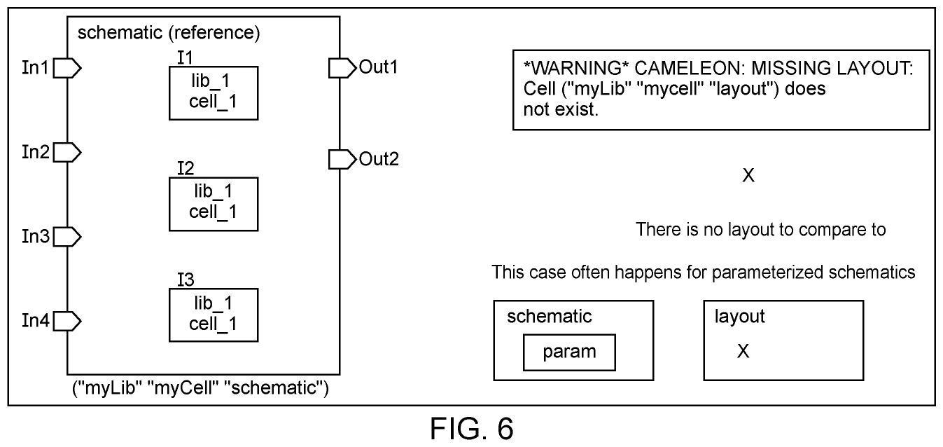

With reference to FIG. 6, a schematic graphical diagram is provided to illustrate an instance of missing layout identification that is executable by the computer-implemented method 200 of FIG. 2. As shown in FIG. 6, there is no layout to compare to the schematic as is often the case in parameterized schematics.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A computer-implemented method for layout versus schematic (LVS) checking for a design process of an integrated circuit (IC), the computer-implemented method comprising:
receiving a layout of the IC at multiple hierarchical levels;
receiving a schematic of the IC at the multiple hierarchical levels;
establishing a requirement for name matching;
scanning the layout and the schematic at least at one of the multiple hierarchical levels; and
issuing an alert for one or more name inconsistencies identified during the scanning.

2. The computer-implemented method according to claim 1, wherein:
the scanning comprises comparing cells at one of the multiple hierarchical levels of the layout and the schematic, and
the establishing of the requirement for name matching comprises stipulating that cell names match between the layout and the schematic for the one of the multiple hierarchical levels.

3. The computer-implemented method according to claim 1, wherein:
the scanning comprises comparing cells at one of the multiple hierarchical levels of the layout and the schematic, and
the establishing of the requirement for name matching comprises stipulating that instance names match between the layout and the schematic for the one of the multiple hierarchical levels.

4. The computer-implemented method according to claim 1, wherein:
the scanning comprises comparing pins for every cell at one of the multiple hierarchical levels of the layout and the schematic, and
the establishing of the requirement for name matching comprises stipulating that pin names match between the layout and the schematic for the one of the multiple hierarchical levels.

5. The computer-implemented method according to claim 1, further comprising flagging a missing element in the layout discovered during the scanning.

6. The computer-implemented method according to claim 5, further comprising determining a type of the missing element and storing the type in a record.

7. The computer-implemented method according to claim 1, further comprising automatically correcting the one or more name inconsistencies.

8. A computer program product for layout versus schematic (LVS) checking for a design process of an integrated circuit (IC), the computer program product comprising one or more computer readable storage media having computer readable program code collectively stored on the one or more computer readable storage media, the computer readable program code being executed by a processor of a computer system to cause the computer system to perform a method comprising:
receiving a layout of the IC at multiple hierarchical levels;
receiving a schematic of the IC at the multiple hierarchical levels;
establishing a requirement for name matching;
scanning the layout and the schematic at least at one of the multiple hierarchical levels; and
issuing an alert for one or more name inconsistencies identified during the scanning.

9. The computer program product according to claim 8, wherein:
the scanning comprises comparing cells at one of the multiple hierarchical levels of the layout and the schematic, and
the establishing of the requirement for name matching comprises stipulating that cell names match between the layout and the schematic for the one of the multiple hierarchical levels.

10. The computer program product according to claim 8, wherein:
the scanning comprises comparing cells at one of the multiple hierarchical levels of the layout and the schematic, and
the establishing of the requirement for name matching comprises stipulating that instance names match between the layout and the schematic for the one of the multiple hierarchical levels.

11. The computer program product according to claim 8, wherein:
the scanning comprises comparing pins for every cell at one of the multiple hierarchical levels of the layout and the schematic, and
the establishing of the requirement for name matching comprises stipulating that pin names match between the layout and the schematic for the one of the multiple hierarchical levels.

12. The computer program product according to claim 8, wherein the method further comprises flagging a missing element the layout discovered during the scanning.

13. The computer program product according to claim 12, wherein the method further comprises determining a type of the missing element and storing the type in a record.

14. The computer program product according to claim 8, wherein the method further comprises automatically correcting the one or more name inconsistencies.

15. A computing system comprising:
a processor;
a memory coupled to the processor; and
one or more computer readable storage media coupled to the processor, the one or more computer readable storage media collectively containing instructions that are executed by the processor via the memory to cause the processor to perform steps for layout versus schematic (LVS) checking for a design process of an integrated circuit (IC) comprising:
receiving a layout of the IC at multiple hierarchical levels;
receiving a schematic of the IC at the multiple hierarchical levels;
establishing a requirement for name matching;
scanning the layout and the schematic at least at one of the multiple hierarchical levels; and
issuing an alert for one or more name inconsistencies identified during the scanning.

16. The computing system according to claim 15, wherein:
the scanning comprises comparing cells at one of the multiple hierarchical levels of the layout and the schematic, and
the establishing of the requirement for name matching comprises stipulating that cell names match between the layout and the schematic for the one of the multiple hierarchical levels.

17. The computing system according to claim 15, wherein:
the scanning comprises comparing cells at one of the multiple hierarchical levels of the layout and the schematic, and
the establishing of the requirement for name matching comprises stipulating that instance names match between the layout and the schematic for the one of the multiple hierarchical levels.

18. The computing system according to claim 15, wherein:
the scanning comprises comparing pins for every cell at one of the multiple hierarchical levels of the layout and the schematic, and
the establishing of the requirement for name matching comprises stipulating that pin names match between the layout and the schematic for the one of the multiple hierarchical levels.

19. The computing system according to claim 15, wherein the steps for the LVS checking for the design process of the IC further comprise:
flagging a missing element in one of the layout and the schematic discovered during the scanning; and
determining a type of the missing element and storing the type in a record.

20. The computing system according to claim 15, wherein the steps for the LVS checking for the design process of the IC further comprise automatically correcting the one or more name inconsistencies.
